(19) United States
(12) Patent Application Publication
(10) Pub. No.: US 2026/0360287 A1
(43) Pub. Date: Nov. 12, 2026

(54) Shift Register, Gate Driving Circuit, Array Substrate, and Display Device

(71) Applicants: Chongqing BOE Display Technology Co., Ltd., Beibei District, Chongqing (CN); BOE TECHNOLOGY GROUP CO., LTD., Chaoyang District, Beijing (CN)

(72) Inventors: Rui Wang, Beijing (CN); Shouqiang Zhang, Beijing (CN); Runxin Zhang, Beijing (CN); Hongtao Weng, Beijing (CN); Ming Hu, Beijing (CN); Zhi Huang, Beijing (CN); Guoqiang Tang, Beijing (CN); Xueguang Hao, Beijing (CN); Chen Xu, Beijing (CN)

(21) Appl. No.: 19/120,254

(22) PCT Filed: Jul. 11, 2024
(86) PCT No.: PCT/CN2024/104933

§ 371 Date: Apr. 11, 2025

(30) Foreign Application Priority Data
Aug. 1, 2023 (CN) 202310961260.4

(51) Int. Cl. G09G 3/20; G11C 19/28

(52) U.S. Cl. CPC G09G 3/20; G11C 19/28; G09G 2300/0426; G09G 2310/0286; G09G 2310/08

(57) ABSTRACT

A shift register includes a first input circuit, a second input circuit, a first output circuit and an output control circuit. The first input circuit is configured to transmit an input signal from a signal input terminal to a first note. The second input circuit is configured to transmit a second clock signal from a second clock signal terminal to a second node. The first output circuit is configured to transmit the second clock signal from the second clock signal terminal to a signal output terminal, and transmit a first voltage signal from a first voltage signal terminal to the signal output terminal. The output control circuit is configured to transmit a second voltage signal from a second voltage signal terminal to the second node coupled thereto of the signal output terminal coupled thereto.

### CROSS-REFERENCE TO RELATED APPLICATIONS

This application is the United States national phase of International Patent Application No. PCT/CN2024/104933 filed Jul. 11, 2024, and claims priority to Chinese Patent Application No. 202310961260.4 filed Aug. 1, 2023, the disclosures of which are hereby incorporated by reference in their entireties.

### BACKGROUND OF THE INVENTION

### Field of the Invention

The present disclosure relates to the field of display technologies, and in particular, to a shift register, a gate driving circuit, an array substrate, and a display device.

### Description of Related Art

A gate driving circuit is an important constituent of a display device. The gate driving circuit may include a plurality of stages of shift registers connected in cascade, with each stage of shift registers may be electrically connected to a wiring in the display device. The gate driving circuit can output scanning signals into a plurality of wirings (such as gate lines or enable signal lines) in the display device line by line, so as to enable the display device to display images.

### SUMMARY OF THE INVENTION

In an aspect, a shift register is provided. The shift register includes a first input circuit, a second input circuit, a first output circuit and an output control circuit.

The first input circuit is coupled to a signal input terminal, a first clock signal terminal and a first node, and the first input circuit is configured to, under control of a first clock signal from the first clock signal terminal, transmit an input signal from the signal input terminal to the first node.

The second input circuit is coupled to a second clock signal terminal, a second node and a third node, and the second input circuit is configured to, under control of a voltage of the third node, transmit a second clock signal from the second clock signal terminal to the second node.

The first output circuit is coupled to the first node, the second node, a first voltage signal terminal, the second clock signal terminal and a signal output terminal, and the first output circuit is configured to, under control of a voltage of the first node, transmit the second clock signal from the second clock signal terminal to the signal output terminal, and under control of a voltage of the second node, transmit a first voltage signal from the first voltage signal terminal to the signal output terminal.

The output control circuit is coupled to a second voltage signal terminal and a control signal terminal, and further coupled to the second node or the signal output terminal, and the output control circuit is configured to, under control of a control signal from the control signal terminal, transmit a second voltage signal from the second voltage signal terminal to the second node or the signal output terminal.

In some embodiments, the output control circuit is coupled to the second voltage signal terminal, the control signal terminal and the second node; and of the voltage signals received by the first voltage signal terminal and the second voltage signal terminal, one is an operating voltage enabling a transistor to which the operating voltage is applied to be turned on, and the other is a non-operating voltage enabling a transistor to which the operating voltage is applied to be turned off.

In some embodiments, the output control circuit includes a ninth transistor, a first electrode of the ninth transistor being electrically connected to the second voltage signal terminal, a second electrode of the ninth transistor being electrically connected to the second node, and a third electrode of the ninth transistor being electrically connected to the control signal terminal.

In some embodiments, the output control circuit is coupled to the second voltage signal terminal, the control signal terminal and the signal output terminal; and the voltage signals received by the first voltage signal terminal and the second voltage signal terminal are the same.

In some embodiments, the output control circuit includes a ninth transistor. A first electrode of the ninth transistor is electrically connected to the second voltage signal terminal, a second electrode of the ninth transistor is electrically connected to the signal output terminal, and a third electrode of the ninth transistor is electrically connected to the control signal terminal.

In some embodiments, the first input circuit includes a first transistor, a first electrode of the first transistor being electrically connected to the signal input terminal, a second electrode of the first transistor being electrically connected to the first node, and a third electrode of the first transistor being electrically connected to the first clock signal terminal; and/or the second input circuit includes a second transistor and a first capacitor. A first electrode of the second transistor is electrically connected to the second clock signal terminal, a second electrode of the second transistor is electrically connected to the second node, and a third electrode of the second transistor is electrically connected to the third node. A first electrode plate of the first capacitor is electrically connected to the second clock signal terminal, and a second electrode plate of the first capacitor is electrically connected to the third node.

In some embodiments, the first output circuit includes a seventh transistor, an eighth transistor, a second capacitor and a third capacitor. A first electrode of the seventh transistor is electrically connected to the second clock signal terminal, a second electrode of the seventh transistor is electrically connected to the signal output terminal, and a third electrode of the seventh transistor is electrically connected to the first node. A first electrode of the eighth transistor is electrically connected to the first voltage signal terminal, a second electrode of the eighth transistor is electrically connected to the signal output terminal, and a third electrode of the eighth transistor is electrically connected to the second node. A first electrode plate of the second capacitor is electrically connected to the first node, and a second electrode plate of the second capacitor is electrically connected to the signal output terminal. A first electrode plate of the third capacitor is electrically connected to the second node, and a second electrode plate of the third capacitor is electrically connected to the first voltage signal terminal.

In some embodiments, the shift register further includes a control circuit. The control circuit is coupled to the first node, the second node, the third node and the first voltage signal terminal, and the control circuit is configured to, under the control of the voltage from the first node, transmit the first voltage signal from the first voltage signal terminal to the second node and the third node, and under the control of the voltage from the second node, transmit the first voltage signal from the first voltage signal terminal to the first node.

In some embodiments, the control circuit includes a first control sub-circuit and a second control sub-circuit. The first control sub-circuit is coupled to the first node, the second node and the first voltage signal terminal, and the first control sub-circuit is configured to, under the control of the voltage of the second node, transmit the first voltage signal from the first voltage signal terminal to the first node. The second control sub-circuit is coupled to the first node, the second node, the third node and the first voltage signal terminal, and the second control sub-circuit is configured to, under the control of the voltage of the first node, transmit the first voltage signal from the first voltage signal terminal to the second node and the third node.

In some embodiments, the first control sub-circuit is further coupled to the second clock signal terminal, and the first control sub-circuit includes a third transistor and a fourth transistor. A first electrode of the third transistor is electrically connected to the first voltage signal terminal, a second electrode of the third transistor is electrically connected to the first node, and a third electrode of the third transistor is electrically connected to the second node. A first electrode of the fourth transistor is electrically connected to the second electrode of the third transistor, a second electrode of the fourth transistor is electrically connected to the first node, and a third electrode of the fourth transistor is electrically connected to the second clock signal terminal.

And/or, the second control sub-circuit includes a fifth transistor and a sixth transistor. A first electrode of the fifth transistor is electrically connected to the first voltage signal terminal, a second electrode of the fifth transistor is electrically connected to the third node, and a third electrode of the fifth transistor is electrically connected to the first node. A first electrode of the sixth transistor is electrically connected to the first voltage signal terminal, a second electrode of the sixth transistor is electrically connected to the second node, and a third electrode of the sixth transistor is electrically connected to the first node.

In another aspect, a gate driving circuit is provided. The gate driving circuit includes a plurality of first shift registers connected in cascade, where the first shift registers are shift registers each as described in any of the above embodiments.

In some embodiments, except for a first shift register at a last stage, for first shift registers at every two adjacent stages, a control signal terminal of a first shift register at a former stage is coupled to a signal output terminal of a first shift register at a latter stage.

In some embodiments, the gate driving circuit further includes a second shift register. The second shift register includes a first input circuit, a second input circuit, a control circuit and a first output circuit. A signal input terminal of the second shift register is connected to a signal output terminal of the first shift register at the last stage, and a control signal terminal of the first shift register at the last stage is connected to a signal output terminal of the second shift register.

In yet another aspect, an array substrate is provided. The array substrate has a display area and a peripheral area located on at least one side of the display area. The array substrate includes a base and the gate driving circuit as described in any of the above embodiments, where the gate driving circuit is disposed on the base and located in the peripheral area.

In some embodiments, the array substrate further includes a first voltage signal line and a second voltage signal line. The first voltage signal line is disposed on a side of the gate driving circuit away from the display area. The second voltage signal line overlaps with the gate driving circuit and divides a first shift register of the gate driving circuit into a first circuit and a second circuit, where the first circuit is farther away from the display area than the second circuit. The first circuit includes a first input circuit, a second input circuit, a control circuit and an output control circuit. The second circuit includes a first output circuit.

In some embodiments, the control circuit includes a first control sub-circuit and a second control sub-circuit. The array substrate further includes a first active pattern. The first active pattern includes a first straight line segment, a second straight line segment, a third straight line segment and a fourth straight line segment. The first straight line segment and the third straight line segment both are substantially parallel to the first voltage signal line, and the first straight line segment is closer to the first voltage signal line than the third straight line segment; and the second straight line segment and the fourth straight line segment both are substantially perpendicular to the first voltage signal line.

The first straight line segment includes a first portion and a second portion, the first portion and the second portion being located on two opposite sides of the second straight line segment; and the second straight line segment, the third straight line segment, and the fourth straight line segment are connected in sequence at end portions thereof, and the third straight line segment and the first portion are located on a same side of the second straight line segment.

Active layers of transistors included in the first control sub-circuit are located in the second portion; and in transistors included in the second control sub-circuit, an active layer of a part of the transistors is located in the first portion, and an active layer of the other part of the transistors is located in the third straight line segment.

In some embodiments, the output control circuit is coupled to a second voltage signal terminal, a control signal terminal and a second node. The array substrate further includes a first gate line, a second gate line and a second active pattern.

The first gate line is substantially perpendicular to the first voltage signal line, and the first gate line overlaps with the second portion and is connected to the second control sub-circuit and the first output circuit. The second gate line is substantially perpendicular to the first voltage signal line, and the second gate line is connected to the first voltage signal line and the first output circuit.

The second active pattern is substantially parallel to the first voltage signal line and located between the first gate line and the second gate line, where one end of the second active pattern is connected to the first gate line, and the other end of the second active pattern is connected to the second voltage signal line. An active layer of a transistor included in the output control circuit is located in the second active pattern.

In some embodiments, the array substrate further includes a second clock signal line, a third gate line, a first connection line and a first cascade line. The second clock signal line is disposed on the side of the gate driving circuit away from the display area and substantially parallel to the first voltage signal line.

The third gate line is substantially perpendicular to the first voltage signal line, where one end of the third gate line is connected to the second clock signal line, and the other end of the third gate line overlaps with the second portion. The first connection line is connected to an end portion of the fourth straight line segment away from the third straight line segment, and connected to an end portion of the third gate line away from the first voltage signal line.

For shift registers at two adjacent stages, one end of the first cascade line overlaps with a second active pattern of a shift register at a former stage, and the other end of the first cascade line passes through the first connection line and the second voltage signal line and is connected to a signal output terminal of a shift register at a latter stage.

In some embodiments, the first cascade line includes a fourth gate line and a second connection line. The fourth gate line is located between the first gate line and the second gate line; and one end of the fourth gate line overlaps with the second active pattern of the shift register at the former stage, and the other end of the fourth gate line is connected to the second connection line; and the second connection line is connected to the fourth gate line and the signal output terminal of the shift register at the latter stage.

In some embodiments, the output control circuit is coupled to a second voltage signal terminal, a control signal terminal and a signal output terminal. The array substrate further includes a first gate line, a second gate line and a second active pattern.

The first gate line is substantially perpendicular to the first voltage signal line, and the first gate line overlaps with the second portion and is connected to the second control sub-circuit and the first output circuit. The second gate line is substantially perpendicular to the first voltage signal line, and the second gate line is connected to the first voltage signal line and the first output circuit.

The second active pattern is substantially perpendicular to the first voltage signal line and located between the first gate line and the second gate line, where one end of the second active pattern is connected to the signal output terminal, and the other end of the second active pattern is connected to the first voltage signal line; and an active layer of a transistor included in the output control circuit is located in the second active pattern.

In some embodiments, the array substrate further includes a second clock signal line, a third gate line, a first connection line and a first cascade line. The second clock signal line is disposed on the side of the gate driving circuit away from the display area and substantially parallel to the first voltage signal line.

The third gate line is substantially perpendicular to the first voltage signal line, where one end of the third gate line is connected to the second clock signal line, and the other end of the third gate line overlaps with the second portion. The first connection line is connected to an end portion of the fourth straight line segment away from the third straight line segment, and is connected to an end portion of the third gate line away from the first voltage signal line.

For shift registers at two adjacent stages, one end of the first cascade line overlaps with a second active pattern of a shift register at a former stage, and the other end of the first cascade line passes through the first connection line and the second voltage signal line and is connected to a signal output terminal of a shift register at a latter stage.

In some embodiments, the first cascade line includes a fourth gate line and a second connection line. The fourth gate line is located between the first gate line and the second gate line; and one end of the fourth gate line overlaps with the second active pattern of the shift register at the former stage, and the other end of the fourth gate line is connected to the second connection line across another first cascade line; and the second connection line is connected to the fourth gate line and the signal output terminal of the shift register at the latter stage.

In some embodiments, an end portion of the first connection line connected to the fourth straight line segment is farther away from the first voltage signal line than an end portion of the first connection line connected to the third gate line.

In still another aspect, a display device is provided. The display device includes the array substrate as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device in accordance with some embodiments;

FIG. 2 is a structural diagram of another display device in accordance with some embodiments;

FIG. 3 is a sectional view taken along the section line A-A′ in FIG. 1;

FIG. 4 is a structural diagram of a display panel in accordance with some embodiments;

FIG. 5 is a sectional view taken along the section line B-B′ in FIG. 4;

FIG. 6 is a structural diagram of a gate driving circuit in accordance with some embodiments;

FIG. 7 is a structural block diagram of a shift register in accordance with some embodiments;

FIG. 8 is a structural block diagram of another shift register in accordance with some embodiments;

FIG. 9 is a circuit diagram of the shift register shown in FIG. 7;

FIG. 10 is a circuit diagram of the shift register shown in FIG. 8;

FIG. 11 is a timing diagram of the shift register shown in FIG. 9;

FIG. 12 is a simulation comparison diagram of an output voltage of a signal output terminal at a floating phase in the related art, and an output voltage of a signal output terminal at a corresponding phase in some embodiments of the present disclosure;

FIG. 13 is a circuit diagram of a second shift register in accordance with some embodiments;

FIG. 14 is a structural diagram of a shift register of an array substrate in accordance with some embodiments;

FIG. 15 is a structural diagram of another shift register of an array substrate in accordance with some embodiments;

FIG. 16 is a structural diagram of a semiconductor layer of the array substrate shown in FIGS. 14 and 15;

FIG. 17 is a structural diagram of a first gate conductive layer and a second gate conductive layer of the array substrate shown in FIG. 14;

FIG. 18 is a structural diagram of a first gate conductive layer and a second gate conductive layer of the array substrate shown in FIG. 15;

FIG. 19 is a structural diagram of a source-drain conductive layer of the array substrate shown in FIG. 14; and

FIG. 20 is a structural diagram of a source-drain conductive layer of the array substrate shown in FIG. 15.

### DESCRIPTION OF THE INVENTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of (multiple)” means two or more unless otherwise specified.

Some embodiments may be described using the terms “coupled,” “connected” and their derivatives. The term “connected” should be understood in a broad sense, for example, the term “connected” may represent a fixed connection, or a detachable connection, or a one-piece connection; alternatively, the term “connected” may represent a direct connection, or an indirect connection through an intermediate medium. The term “coupled,” for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].

The use of the phrase “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation, or other action that is “based on” one or more of the stated conditions or values may, in practice, be based on or according to additional conditions or values exceeding those stated.

As used herein, “about,” “approximately” or “substantially” are inclusive of the stated value and mean within an acceptable range of deviation for the particular value as determined by one of ordinary skill in the art, taking into account the measurements in question and the errors associated with measurement of a particular quantity (i.e., limitations of the measurement system). For example, “about” may mean that a value possesses one or more standard deviations, or that the deviation is within ±30%, ±20%, ±10%, ±5% of the stated value.

The terms such as “parallel,” “perpendicular” and “equal” as used herein include a stated condition and a condition similar to the stated condition, the range of the similar condition is within an acceptable range of deviation, and the acceptable range of deviation is determined by, for example, a person of ordinary skill in the art, considering measurement in question and errors (i.e., limitations of a measurement system) associated with measurement of a particular quantity. For example, the term “parallel” includes an absolute parallelism and an approximate parallelism, and an acceptable range of a deviation of the approximate parallelism may be, for example, a deviation within 5°; the term “perpendicular” includes an absolute perpendicularity and an approximate perpendicularity, and an acceptable range of a deviation of the approximate perpendicularity may also be, for example, a deviation within 5°; and the term “equal” includes an absolute equality and an approximate equality, and an acceptable range of deviation of the approximate equality may be, for example, a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views that are schematic illustrations of idealized embodiments. In the accompanying drawings, thicknesses of layers and sizes of regions/areas are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

In the present disclosure, unless otherwise defined, all terms (including technical terms and scientific terms) used herein each have the same meaning as commonly understood by a person of ordinary skill in the art to which the present disclosure belongs. It will be further understood that, unless expressly defined herein, terms (such as terms defined in dictionaries commonly used) should be interpreted as having meanings consistent with their meanings in the context of the field to which they relate, and should not be interpreted as having an ideal or overly formalized meaning.

In the present disclosure, terms such as “beneath,” “under/below,” “on,” “over/above,” and similar terms are used to interpret relationships/associations of components shown in accompanying drawings. These terms may be relative concepts, which are described based on orientations represented in the accompanying drawings, as well as based on an order in which process/formation steps are performed, but are not limited thereto.

The term “opposite” means that a first element may be directly or indirectly opposite to a second element. In the case of a third element interposed between the first element and the second element, the first element and the second element may be understood as being indirectly opposite to each other, although still opposite to each other.

In embodiments of the present disclosure, transistors employed may be thin film transistors (TFT), field effect transistors (such as metal oxide semiconductors, MOS for short), or other switching devices with the same characteristics, and the embodiments of the present disclosure are all stated by taking the thin film transistor as an example.

In the embodiments of the present disclosure, a third electrode of each thin film transistor employed is a gate of the thin film transistor, a first electrode is one of source and drain of the thin film transistor, and a second electrode is the other of the source and drain of the thin film transistor. Since the source and drain of the thin film transistor may be symmetrical in structure, the source and drain thereof may be indistinguishable in structure. That is, the first and second electrodes of the thin film transistor in the embodiments of the present disclosure may be indistinguishable in structure. For example, in a case where the transistor is a P-type transistor, the first electrode of the transistor is the source and the second electrode is the drain. For example, in a case where the transistor is an N-type transistor, the first electrode of the transistor is the drain and the second electrode is the source.

In the embodiments of the present disclosure, a capacitor may be a capacitive device made separately through processes, such as by making dedicated capacitive electrodes to form the capacitive device, in which each capacitive electrode of the capacitor may be available by a metal layer, a semiconductor layer (e.g., doped polycrystalline silicon), or the like. Alternatively, the capacitor may be available by a parasitic capacitance between transistors, or may be available by the transistor itself with other devices or lines, or may be available by a parasitic capacitance between lines of a circuit itself.

In the embodiments of the present disclosure, nodes such as a first node and a second node do not represent actually existing components, but rather represent junctions of related electrical connections in a circuit diagram. That is, these nodes are nodes that are equivalently formed by the junctions of the related electrical connections in the circuit diagram.

In the embodiments of the present disclosure, the “operating voltage” refers to a voltage that enables a transistor to which this voltage is applied to be turned on; and correspondingly, the “non-operating voltage” refers to a voltage that does not enable a transistor to which this voltage is applied to be turned on.

In the embodiments of the present disclosure, the “low voltage” refers to a voltage that enables a P-type transistor to which this voltage is applied to be turned on while does not enable an N-type transistor to which this voltage is applied to be turned on (i.e., the N-type transistor will be caused to be turned off); and correspondingly, the “high voltage” refers to a voltage that enables an N-type transistor to which this voltage is applied to be turned on while does not enable a P-type transistor to which this voltage is applied to be turned on (i.e., the P-type transistor will be caused to be turned off).

In the following, the circuits provided by the embodiments of the present disclosure are described by taking an example where the transistors therein are all P-type transistors.

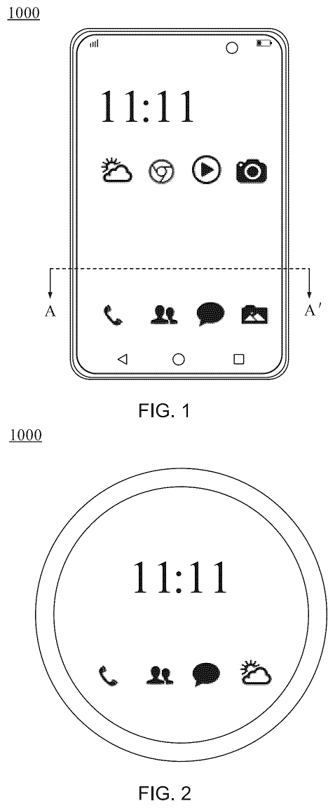

As shown in FIGS. 1 and 2, some embodiments of the present disclosure provide a display device 1000. The display device 1000 may be any device that can display an image whether in motion (e.g., video) or stationary (e.g., a still image), and whether textual or pictorial.

For example, the display device 1000 may be any product or component having a display function, such as a television, a notebook computer, a tablet computer, a mobile phone, a personal digital assistant (PDA), a navigator, a wearable device, or a virtual reality (VR) device.

By way of an example, as shown in FIG. 1, the display device 1000 may be a portable display product; for example, the display device 1000 may be a mobile phone shown in FIG. 1. By way of another example, referring to FIG. 2, the display device 1000 may be a wearable device; for example, the display device 1000 may be a watch shown in FIG. 2.

In the following, some embodiments of the present disclosure are stated schematically by taking an example where the display device 1000 described above is a mobile phone shown in FIG. 1, but the embodiments of the present disclosure are not limited thereto.

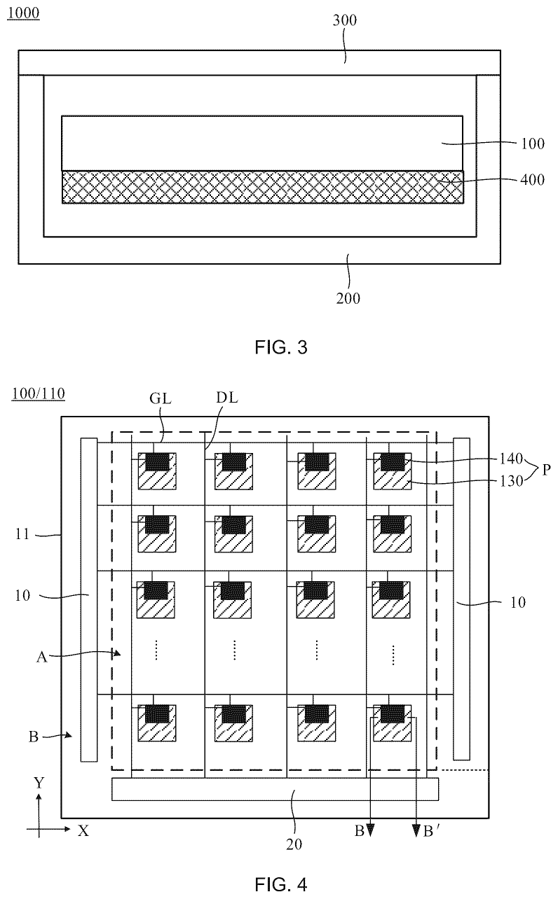

In some embodiments, referring to FIG. 3, the display device 1000 includes a display panel 100.

Here, the display panel 100 includes a light-exit side and a non-light-exit side provided opposite to each other, in which the light-exit side is a side of the display panel 100 used for display, i.e., the upper side in FIG. 3.

For example, as shown in FIG. 3, the display device 1000 described above may further include a housing 200, a cover plate 300 and a circuit board 400, as well as other electronic accessories.

Referring to FIG. 3, the cover plate 300 may be a glass cover plate of a single layer, or may include multiple sub-cover plates in stack, which are not specifically limited in the embodiments of the present disclosure.

As shown in FIG. 3, a longitudinal cross-section of the housing 200 may be, for example, U-shaped, the display panel 100 and the circuit board 400 are disposed in the housing 200, and the cover plate 300 is disposed at an opening of the housing 200. Here, the circuit board 400 is disposed on a side of the display panel 100 away from the cover plate 300, and the circuit board 400 is connected to the display panel 100 to provide required display signals to the display panel 100.

Various types of display panels may be applied as the display panel 100, which may be selected and set according to actual needs.

For example, the display panel 100 may be any one of an organic light-emitting diode display panel, a quantum dot light-emitting diode display panel, a micro light-emitting diode display panel, a liquid crystal display panel, a plasma display panel, a field emission display panel, an electrowetting display panel, an electrophoretic display panel, etc., which are not specifically limited in the embodiments of the present disclosure.

In the following, some embodiments of the present disclosure are stated schematically by taking an example where the display panel 100 is an organic light-emitting diode display panel, but implementations of the present disclosure are not limited thereto, and any other display panel 100 may be contemplated as well as long as the same technical concept is applied.

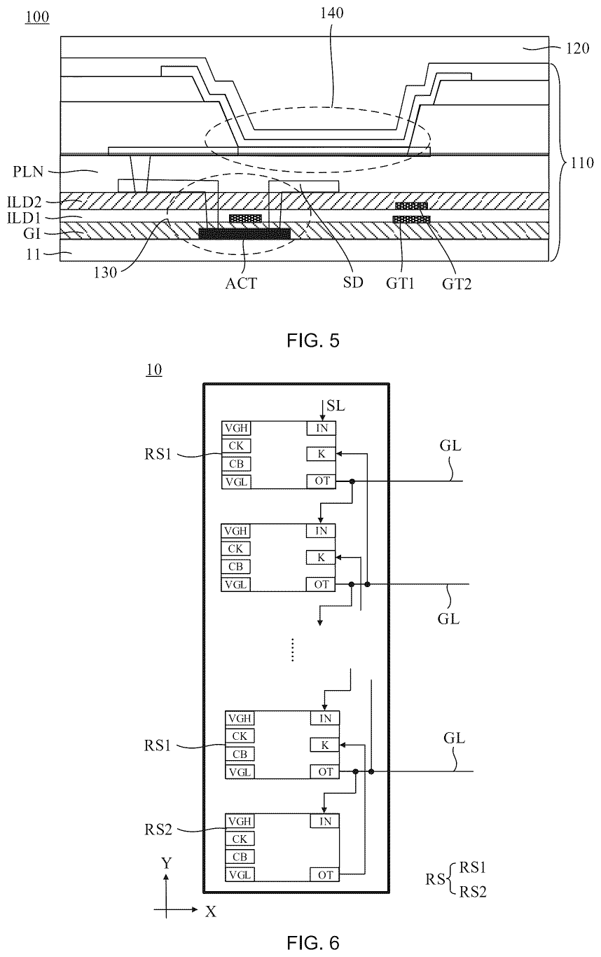

In some embodiments, referring to FIG. 5, the display panel 100 includes an array substrate 110 and an encapsulation layer 120 for encapsulating the array substrate 110, in which the encapsulation layer 120 may be an encapsulation film or an encapsulation substrate, which are not specifically limited in the embodiments of the present disclosure.

In some embodiments, referring to FIGS. 4 and 5, the array substrate 110 has a display area A, i.e., an area for displaying images, which is configured to allow a plurality of sub-pixels P to be provided therein.

For example, referring to FIGS. 4 and 5, the array substrate 110 includes a base 11 and a plurality of sub-pixels P. The plurality of sub-pixels P are provided on the base 11 and are located in the display area A.

Various types of bases may be applied as the base 11, which may be selected and set according to actual needs.

By way of an example, the base 11 may be a rigid base. For example, the rigid base is a glass base or a polymethyl methacrylate (PMMA) base.

By way of another example, the base 11 may be a flexible base. For example, the flexible base is a polyethylene terephthalate (PET) base, a polyethylene naphthalate two formic acid glycol ester (PEN) base, or a polyimide (PI) base.

The plurality of sub-pixels P described above each include a pixel circuit 130 and a light-emitting device 140, in which the plurality of sub-pixels P may be arranged in multiple rows and multiple columns, with each row including multiple sub-pixels P arranged along a first direction X, and each column including multiple sub-pixels P along a second direction Y. Here, the first direction X intersects the second direction Y. For example, the first direction X is substantially perpendicular to the second direction Y.

It will be noted that the first direction X is a row direction in which the plurality of sub-pixels P are arranged, and the second direction Y is a column direction in which the plurality of sub-pixels P are arranged.

In some embodiments, referring to FIG. 4, the array substrate 110 further has a peripheral area B disposed on at least one side of the display area A. The peripheral area B is an area in which no images are displayed, which is configured to allow a display driving circuit to be provided therein.

For example, referring to FIG. 4, the array substrate 110 further includes a gate driving circuit 10 and a source driving circuit 20 that are disposed on the base 11 and located in the peripheral area B.

Here, referring to FIGS. 4 and 6, the gate driving circuit 10 includes a plurality of stages of shift registers RS connected in cascade, where a shift register RS may be electrically connected to at least one row of sub-pixels P. For example, a shift register RS is electrically connected to one row of sub-pixels P.

It will be noted that some shift registers RS (such as a second shift register RS2 in FIG. 6) may merely function as outputting cascade signals and are not connected to the sub-pixel P. The specific description may be referred to below, and the embodiments of the present disclosure are not specifically described here.

Here, the plurality of stages connected in cascade means that for every two adjacent shift registers RS, a signal input terminal IN of a shift register RS at a latter stage is coupled to a signal output terminal OT of a shift register RS at a former stage. A signal input IN of a shift register RS at the first stage is coupled to an initialization signal line SL.

In some embodiments, referring to FIG. 4, the array substrate 110 further includes a plurality of gate lines GL and a plurality of data lines DL that are disposed on the base 11.

Here, the plurality of gate lines GL extend substantially along the first direction X, where a gate line GL may be electrically connected to at least one row of sub-pixels P; and the plurality of data lines DL extend substantially along the second direction Y, where a data line DL may be electrically connected to at least one column of sub-pixels P.

In this case, a shift register RS in the gate driving circuit 10 may be electrically connected to a row of sub-pixels P through a gate line GL, and the source driving circuit 20 may be electrically connected to a column of sub-pixels P through a data line DL.

Based on the above, the gate driving circuit 10 may drive all rows of sub-pixels P in sequence row by row from a single side of the display area A, i.e., with a single-sided driving; alternatively, the gate driving circuit 10 may drive all rows of sub-pixels P from two opposite sides of the display area A in sequence alternately, i.e., with an alternate driving; yet alternatively, the gate driving circuit 10 may drive all rows of sub-pixels P from two opposite sides of the display area A in sequence row by row at the same time, i.e., with a double-sided driving.

In the following, some embodiments of the present disclosure are stated schematically by taking an example where the driving method of the gate driving circuit 10 described above is a single-sided driving, but the implementations of the present disclosure are not limited thereto, and any other driving method can be contemplated as well, as long as the same technical concept is applied.

In the related art, there exists a floating (Float) phase during the process of providing signals to gate lines by the gate driving circuit, i.e., the gate driving circuit does not provide any signals to gates during this phase. In this way, a voltage of a gate line will be easily disturbed by the coupling with other signal lines (such as data lines) during the floating (Float) phase, resulting in fluctuations (e.g., a voltage drop) in the voltage of this gate line, which affects the stability of the entire output waveform of the gate driving circuit, thereby causing erroneous writing or writing failure of the data of the sub-pixels P, and affecting the display quality.

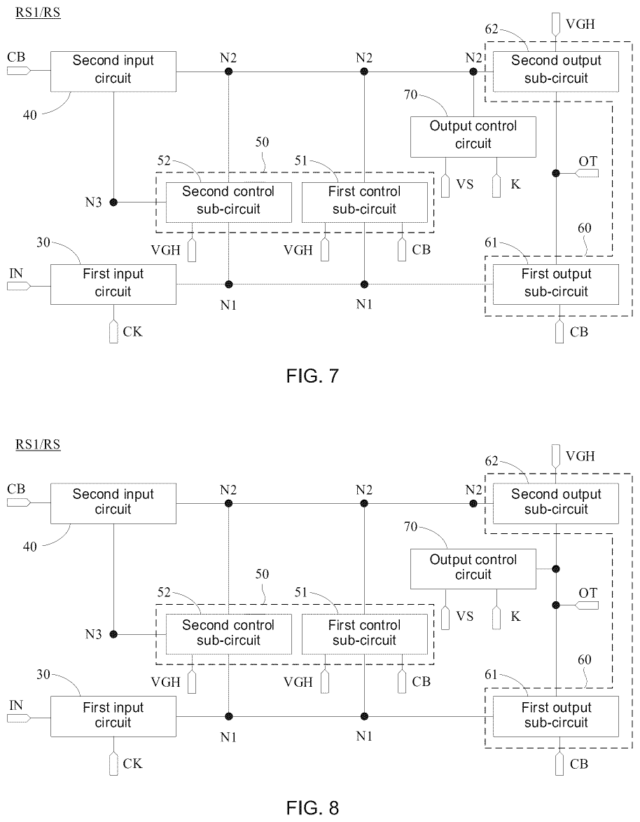

In light of this, referring to FIGS. 7 and 8, some embodiments of the present disclosure provide a shift register RS, which includes a first input circuit 30, a second input circuit 40, a control circuit 50, a first output circuit 60, and an output control circuit 70.

In some examples, referring to FIGS. 7 and 8, the first input circuit 30 is coupled to a signal input terminal IN, a first clock signal terminal CK and a first node N1. The first input circuit 30 is configured to, under the control of a first clock signal from the first clock signal terminal CK, transmit an input signal from the signal input terminal IN to the first node N1.

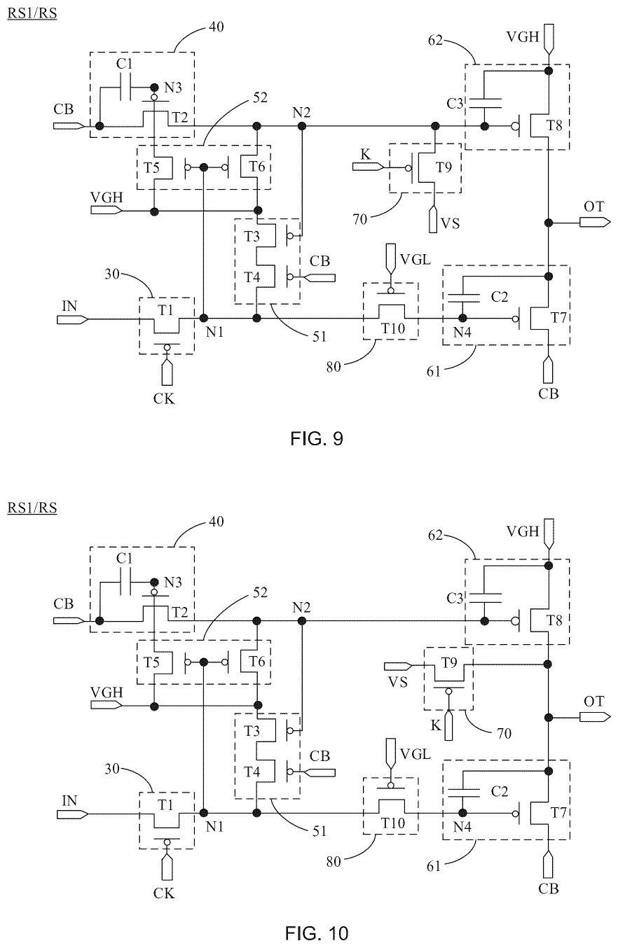

For example, as shown in FIGS. 9 and 10, the first input circuit 30 includes a first transistor T1. A first electrode of the first transistor T1 is electrically connected to the signal input terminal IN, a second electrode of the first transistor T1 is electrically connected to the first node N1, and a third electrode of the first transistor T1 is electrically connected to the first clock signal terminal CK.

In some examples, referring to FIGS. 7 and 8, the second input circuit 40 is coupled to a second clock signal terminal CB, a second node N2 and a third node N3. The second input circuit 40 is configured to, under the control of a voltage of the third node N3, transmit a second clock signal from the second clock signal terminal CB to the second node N2.

For example, as shown in FIGS. 9 and 10, the second input circuit 40 includes a second transistor T2 and a first capacitor C1. A first electrode of the second transistor T2 is electrically connected to the second clock signal terminal CB, a second electrode of the second transistor T2 is electrically connected to the second node N2, and a third electrode of the second transistor T2 is electrically connected to the third node N3. A first electrode plate of the first capacitor C1 is electrically connected to the second clock signal terminal CB, and a second electrode plate of the first capacitor C1 is electrically connected to the third node N3.

In some examples, referring to FIGS. 7 and 8, the control circuit 50 is coupled to the first node N1, the second node N2, the third node N3 and a first voltage signal terminal VGH. The control circuit 50 is configured to, under the control of a voltage from the first node N1, transmit a first voltage signal from the first voltage signal terminal VGH to the second node N2 and the third node N3, and under the control of a voltage from the second node N2, transmit the first voltage signal from the first voltage signal terminal VGH to the first node N1.

For example, referring to FIGS. 7 and 8, the control circuit 50 includes a first control sub-circuit 51 and a second control sub-circuit 52.

As shown in FIGS. 7 and 8, the first control sub-circuit 51 is coupled to the first node N1, the second node N2 and the first voltage signal terminal VGH. The first control sub-circuit 51 is configured to, under the control of the voltage of the second node N2, transmit the first voltage signal from the first voltage signal terminal VGH to the first node N1.

For example, as shown in FIGS. 9 and 10, the first control sub-circuit 51 includes a third transistor T3. A first electrode of the third transistor T3 is electrically connected to the first voltage signal terminal VGH, a second electrode of the third transistor T3 is electrically connected to the first node N1, and a third electrode of the third transistor T3 is electrically connected to the second node N2.

In addition, as shown in FIGS. 9 and 10, the first control sub-circuit 51 is further coupled to the second clock signal terminal CB, and the first control sub-circuit 51 is configured to, under the control of the voltage of the second node N2 and the second clock signal of the second clock signal end CB, transmit the first voltage signal from the first voltage signal terminal VGH to the first node N1.

In this case, as shown in FIGS. 9 and 10, the first control sub-circuit 51 further includes a fourth transistor T4. The second electrode of the third transistor T3 is electrically connected to a first electrode of the fourth transistor T4, a second electrode of the fourth transistor T4 is electrically connected to the first node N1, and a third electrode of the fourth transistor T4 is electrically connected to the second clock signal terminal CB.

As shown in FIGS. 7 and 8, the second control sub-circuit 52 is coupled to the first node N1, the second node N2, the third node N3 and the first voltage signal terminal VGH. The second control sub-circuit 52 is configured to, under the control of the voltage of the first node N1, transmit the first voltage signal from the first voltage signal terminal VGH to the second node N2 and the third node N3.

For example, as shown in FIGS. 9 and 10, the second control sub-circuit 52 includes a fifth transistor T5 and a sixth transistor T6. A first electrode of the fifth transistor T5 is electrically connected to the first voltage signal terminal VGH, a second electrode of the fifth transistor T5 is electrically connected to the third node N3, and a third electrode of the fifth transistor T5 is electrically connected to the first node N2. A first electrode of the sixth transistor T6 is electrically connected to the first voltage signal terminal VGH, a second electrode of the sixth transistor T6 is electrically connected to the second node N2, and a third electrode of the sixth transistor T6 is electrically connected to the first node N1.

In some examples, referring to FIGS. 7 and 8, the first output circuit 60 is coupled to the first node N1, the second node N2, the first voltage signal terminal VGH, the second clock signal terminal CB, and a signal output terminal OT. The first output circuit 60 is configured to, under control of the voltage of the first node N1, transmit the second clock signal from the second clock signal terminal CB to the signal output terminal OT, and under the control of the voltage of the second node N2, transmit the first voltage signal from the first voltage signal terminal VGH to the signal output terminal OT.

For example, the first output circuit 60 includes a first output sub-circuit 61 and a second output sub-circuit 62.

As shown in FIGS. 7 and 8, the first output sub-circuit 61 is coupled to the first node N1, the second clock signal terminal CB and the signal output terminal OT. The first output sub-circuit 61 is configured to, under the control of the voltage of the first node N1, transmit the second clock signal from the second clock signal terminal CB to the signal output terminal OT.

For example, as shown in FIGS. 9 and 10, the first output sub-circuit 61 includes a seventh transistor T7 and a second capacitor C2. A first electrode of the seventh transistor T7 is electrically connected to the second clock signal terminal CB, a second electrode of the seventh transistor T7 is electrically connected to the signal output terminal OT, and a third electrode of the seventh transistor T7 is electrically connected to the first node N1. A first electrode plate of the second capacitor C2 is electrically connected to the first node N1, and a second electrode plate of the second capacitor C2 is electrically connected to the signal output terminal OT.

As shown in FIGS. 7 and 8, the second output subcircuit 62 is coupled to the second node N2, the first voltage signal terminal VGH and the signal output terminal OT. The second output subcircuit 62 is configured to, under the control of the voltage of the second node N2, transmit the first voltage signal from the first voltage signal terminal VGH to the signal output terminal OT.

For example, as shown in FIGS. 9 and 10, the second output sub-circuit 62 includes an eighth transistor T8 and a third capacitor C3. A first electrode of the eighth transistor T8 is electrically connected to the first voltage signal terminal VGH, a second electrode of the eighth transistor T8 is electrically connected to the signal output terminal OT, and a third electrode of the eighth transistor T8 is electrically connected to the second node N2. A first electrode plate of the third capacitor C3 is electrically connected to the second node N2, and a second electrode plate of the third capacitor C3 is electrically connected to the first voltage signal terminal VGH.

In some examples, referring to FIGS. 7 and 8, the output control circuit 70 is coupled to a second voltage signal terminal VS and a control signal terminal K, and further coupled to the second node N2 or the signal output terminal OT. The output control circuit 70 is configured to, under control of a control signal from the control signal terminal K, transmit the second voltage signal from the second voltage signal terminal VS to the second node N2 or the signal output terminal OT.

For example, as shown in FIG. 7, the output control circuit 70 is coupled to the second voltage signal terminal VS, the control signal terminal K and the second node N2.

For example, as shown in FIG. 9, the output control circuit 70 includes a ninth transistor T9. A first electrode of the ninth transistor T9 is electrically connected to the second voltage signal terminal VS, a second electrode of the ninth transistor T9 is electrically connected to the second node N2, and a third electrode of the ninth transistor T9 is electrically connected to the control signal terminal K.

On this basis, all transistors are P-type transistors or N-type transistors. Of the voltage signals received by the first voltage signal terminal VGH and the second voltage signal terminal VS, one voltage signal is an operating voltage enabling a transistor to which the operating voltage is applied to be turned on, and the other voltage signal is a non-operating voltage enabling a transistor to which the operating voltage is applied to be turned off.

For example, all transistors are P-type transistors, the first voltage signal received at the first voltage signal terminal VGH is a constant high voltage, and the second voltage signal received at the second voltage signal terminal VS is a constant low voltage, i.e., the second voltage signal is less than the first voltage signal.

For example, as shown in FIG. 8, the output control circuit 70 is coupled to the second voltage signal terminal VS, the control signal terminal K and the signal output terminal OT.

For example, as shown in FIG. 10, the output control circuit 70 includes a ninth transistor T9. A first electrode of the ninth transistor T9 is electrically connected to the second voltage signal terminal VS, a second electrode of the ninth transistor T9 is electrically connected to the signal output terminal OT, and a third electrode of the ninth transistor T9 is electrically connected to the control signal terminal K.

On this basis, the voltage signals received by the first voltage signal terminal VGH and the second voltage signal terminal VS are the same. For example, all transistors are P-type transistors, and the voltage signals received at the first voltage signal terminal VGH and the second voltage signal terminal VS are both constant high voltages.

In some embodiments, referring to FIGS. 9 and 10, the shift register RS further includes an isolation sub-circuit 80. The isolation sub-circuit 80 is coupled to the first node N1, a fourth node N4 and a third voltage signal terminal VGL. The first output sub-circuit 61 is coupled to the fourth node N4, i.e., the first output sub-circuit 61 is coupled to the first node N1 via the isolation sub-circuit 80.

Here, the isolation subcircuit 80 is configured to, under the control of a third voltage signal from the third voltage signal terminal VGL, transmit the voltage from the first node N1 to the fourth node N4.

For example, as shown in FIGS. 9 and 10, the isolation subcircuit 80 includes a tenth transistor T10. A first electrode of the tenth transistor T10 is electrically connected to the first node N1, a second electrode of the tenth transistor T10 is electrically connected to the third electrode of the seventh transistor T7, and the third electrode of the tenth transistor T10 is electrically connected to the third voltage signal terminal VGL.

It will be noted that the third voltage signal received at the third voltage signal terminal VGL is a constant operating voltage. For example, the tenth transistor T10 is a P-type transistor, and the third voltage signal received at the third voltage signal terminal VGL is a constant low voltage.

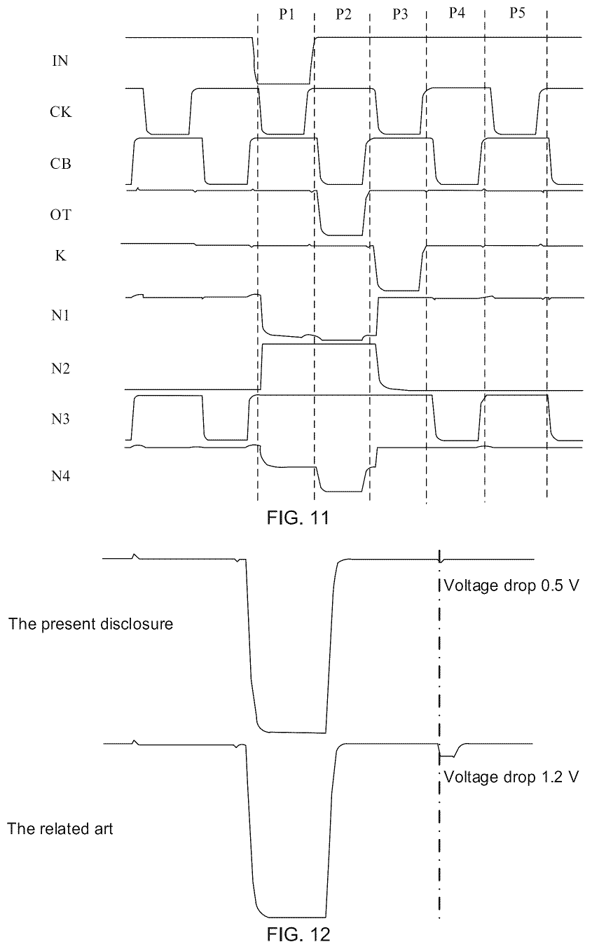

FIG. 11 is a timing diagram of the shift register shown in FIG. 9. The timing of the shift register of some embodiments of the present disclosure is exemplarily described below in conjunction with FIGS. 9 and 11.

As shown in FIG. 11, at the first phase P1, the input signal received by the input signal terminal IN is a low voltage, the first clock signal received by the first clock signal terminal CK is a low voltage, the second clock signal received by the second clock signal terminal CB is a high voltage, and the control signal received by the control signal terminal K is a high voltage.

In this case, in conjunction with FIG. 9, the first transistor T1 is turned on under the control of the first clock signal of the first clock signal terminal CK, and transmits the input signal from the signal input IN to the first node N1, so the first node N1 is at a low voltage. The tenth transistor T10 is turned on and transmits the low voltage of the first node N1 to the fourth node N4, so the fourth node N4 is at a low voltage. The seventh transistor T7 is turned on under the control of the voltage of the first node N1, and transmits the second clock signal received from the second clock signal terminal CB to the signal output terminal OT, so the signal output terminal OT outputs a high voltage.

In addition, the ninth transistor T9 is turned off under the control of the control signal of the control signal terminal K. The fifth transistor T5 and the sixth transistor T6 are turned on under the control of the voltage of the first node N1, and transmit the first voltage signal from the first voltage signal terminal VGH to the third node N3 and the second node N2, respectively, maintaining the voltages of the second node N2 and the third node N3 to be high voltages. The second transistor T2, the third transistor T3, and the eighth transistor T8 are turned off.

As shown in FIG. 11, at the second phase P2, the input signal received by the input signal terminal IN is a high voltage, the first clock signal received by the first clock signal terminal CK is a high voltage, the second clock signal received by the second clock signal terminal CB is a low voltage, and the control signal received by the control signal terminal K is a high voltage.

In this case, in conjunction with FIG. 9, the first transistor T1 is turned off under the control of the first clock signal of the first clock signal terminal CK, the first node N1 maintains the voltage at the previous phase, i.e., the low voltage at the first phase P1, and the fourth node N4 is still at the low voltage. The seventh transistor T7 is turned on under the control of the voltage of the first node N1, and transmits the second clock signal received from the second clock signal terminal CB to the signal output terminal OT, so the signal output terminal OT outputs a low voltage.

In addition, the ninth transistor T9 is turned off under the control of the control signal of the control signal terminal K. The fifth transistor T5 and the sixth transistor T6 are turned on under the control of the voltage of the first node N1, and transmit the first voltage signal from the first voltage signal terminal VGH to the third node N3 and the second node N2, respectively, maintaining the voltages of the second node N2 and the third node N3 to be high voltages. The second transistor T2, the third transistor T3 and the eighth transistor T8 are turned off.

As shown in FIG. 11, at the third phase P3, the input signal received by the input signal terminal IN is a high voltage, the first clock signal received by the first clock signal terminal CK is a low voltage, the second clock signal received by the second clock signal terminal CB is a high voltage, and the control signal received by the control signal terminal K is a low voltage.

In this case, in conjunction with FIG. 9, the ninth transistor T9 is turned on under the control of the control signal of the control signal terminal K, and transmits the second voltage signal from the second voltage signal terminal VS to the second node N2, so the second node N2 is at a low voltage. The eighth transistor T8 is turned on and transmits the first voltage signal from the first voltage signal terminal VGH to the signal output terminal OT, so the signal output terminal OT outputs a high voltage.

In addition, the first transistor T1 is turned on under the control of the first clock signal of the first clock signal terminal CK, and transmits the input signal from the signal input IN to the first node N1, so the first node N1 is at a high voltage. The tenth transistor T10 is turned on, and transmits the high voltage of the first node N1 to the fourth node N4, so the fourth node N4 is at a high voltage. The seventh transistor T7 is turned off.

As shown in FIG. 11, at the fourth phase P4, the input signal received by the input signal terminal IN is a high voltage, the first clock signal received by the first clock signal terminal CK is a high voltage, the second clock signal received by the second clock signal terminal CB is a low voltage, and the control signal received by the control signal terminal K is a high voltage.

In this case, in conjunction with FIG. 9, the ninth transistor T9 is turned off under the control of the control signal of the control signal terminal K. The second transistor T2 is turned on under the control of the second clock signal of the second clock signal terminal CB, and transmits the second clock signal from the second clock signal terminal CB to the second node N2, so the second node N2 is at a low voltage. The eighth transistor T8 is turned on and transmits the first voltage signal from the first voltage signal terminal VGH to the signal output terminal OT, so the signal output terminal OT outputs a high voltage.

In addition, the first transistor T1 is turned off under the control of the first clock signal of the first clock signal terminal CK. The third transistor T3 is turned on under the control of the second node N2, and the fourth transistor T4 is turned on under the control of the second clock signal of the second clock signal terminal CB, so that the first voltage signal of the first voltage signal terminal VGH is transmitted to the first node N1, maintaining the voltage of the first node N1 to be a high voltage. The fourth node N4 is at a high voltage, so the seventh transistor T7 is turned off.

As shown in FIG. 11, at the fifth phase P5, the input signal received by the input signal terminal IN is a high voltage, the first clock signal received by the first clock signal terminal CK is a low voltage, the second clock signal received by the second clock signal terminal CB is a high voltage, and the control signal received by the control signal terminal K is a high voltage.

In this case, in conjunction with FIG. 9, the ninth transistor T9 is turned off under the control of the control signal of the control signal terminal K, and the second transistor T2 is turned off under the control of the second clock signal of the second clock signal terminal CB, so the second node N2 maintains the voltage at the previous phase, i.e., the low voltage at the fourth phase P4. The eighth transistor T8 is turned on under the control of the voltage of the second node N2, and transmits the first voltage signal from the first voltage signal terminal VGH to the signal output terminal OT, so the signal output terminal OT outputs a high voltage.

In addition, the first transistor T1 is turned on under the control of the first clock signal of the first clock signal terminal CK, and transmits the input signal from the signal input IN to the first node N1. The first node N1 is at a high voltage, so the fifth transistor T5 and the sixth transistor T6 are turned off. The fourth node N4 is at a high voltage, so the seventh transistor T7 is turned off.

As can be seen from the above, for the shift register RS provided in the embodiments of the present disclosure, the signal output terminal OT has a voltage signal output at any phase, i.e., the gate line GL does not have a floating phase, which may enhance the stability of the output waveform of the shift register RS, enhance the stability of the shift register RS against interference, and reduce the risk of erroneous writing or writing failure of the data of the sub-pixels P, thereby improving the display quality.

FIG. 12 is a simulation comparison diagram of an output voltage of a signal output terminal at a floating phase in the related art, and the output voltage of the signal output terminal at the corresponding phase in some embodiments of the present disclosure.

As can be seen from FIG. 12, in the related art, the voltage drop of the signal output terminal OT of the shift register RS due to other signal lines (such as data lines DL) is 1.2 V; and in the present disclosure, the voltage drop of the signal output terminal OT of the shift register RS due to other signal lines (such as data lines DL) is 0.5 V, that is, the magnitude of the voltage drop is reduced by 0.7 V compared to the related art. Therefore, the present disclosure may significantly enhance the stability of the output waveform of the shift register RS, enhance the stability of the shift register RS against interference, and reduce the risk of erroneous writing or writing failure of the data of the sub-pixels P, thereby improving the display quality.

In the gate driving circuit 10 provided in some embodiments of the present disclosure, referring to FIGS. 4 and 6, the plurality of stages of shift registers RS connected in cascade include first shift registers RS1, and the first shift registers RS1 are each the shift register RS1 of any of the embodiments described above. Here, a first shift register RS1 at each stage may be coupled, for example, to one row of sub-pixels P.

In some embodiments, referring to FIG. 6, except for a first shift register RS1 at the last stage, for first shift registers RS1 at every two adjacent stages, a control signal terminal K of a first shift register RS1 at the former stage is coupled to a signal output terminal OT of a first shift register RS1 at the latter stage. With this configuration, there is no need to provide a signal line specifically for the control signal terminal K, which may simplify the circuit design.

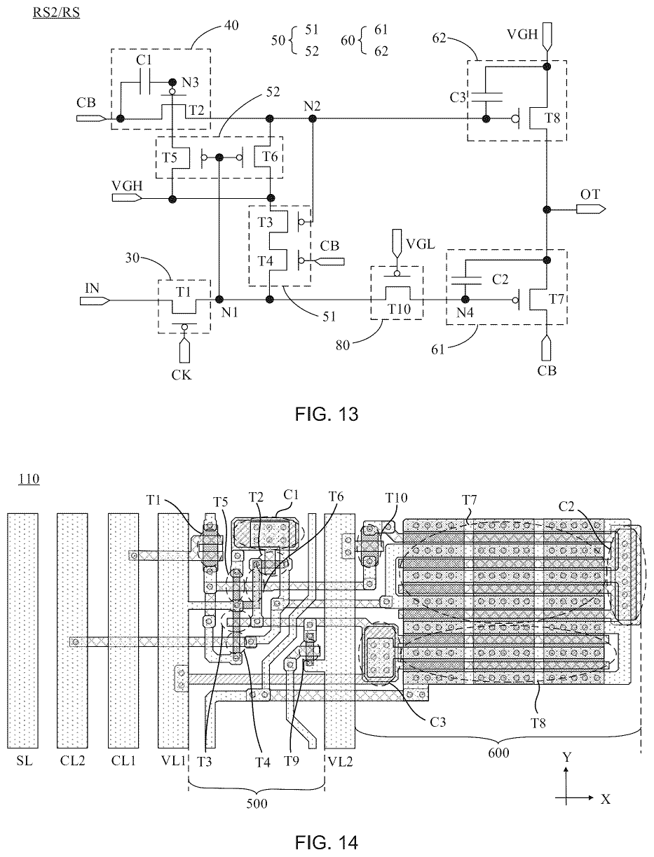

In some embodiments, as shown in FIGS. 6 and 13, the gate driving circuit 10 further includes a second shift register RS2. The second shift register RS2 includes a first input circuit 30, a second input circuit 40, a control circuit 50, and a first output circuit 60. That is, the second shift register RS2 does not include the output control circuit 70 described above.

It will be noted that the second shift register RS2 may further include an isolation subcircuit 80. The structures of the first input circuit 30, the second input circuit 40, the control circuit 50, the first output circuit 60, and the isolation sub-circuit 80 may be referred to above, which will not be repeated here in the embodiments of the present disclosure.

Here, a signal input terminal IN of the second shift register RS2 is connected to a signal output terminal OT of the first shift register RS1 at the last stage, and a control signal terminal K of the first shift register RS1 at the last stage is connected to a signal output terminal OT of the second shift register RS2.

It should be understood that there is a floating phase at the output signal terminal OT of the second shift register RS2. In light of this, in some embodiments of the present disclosure, the signal output terminal OT of the second shift register RS2 is not connected to any sub-pixel P, and the signal output terminal OT of the second shift register RS2 only provides a control signal for a control signal terminal K of a first shift register RS1 at a previous stage.

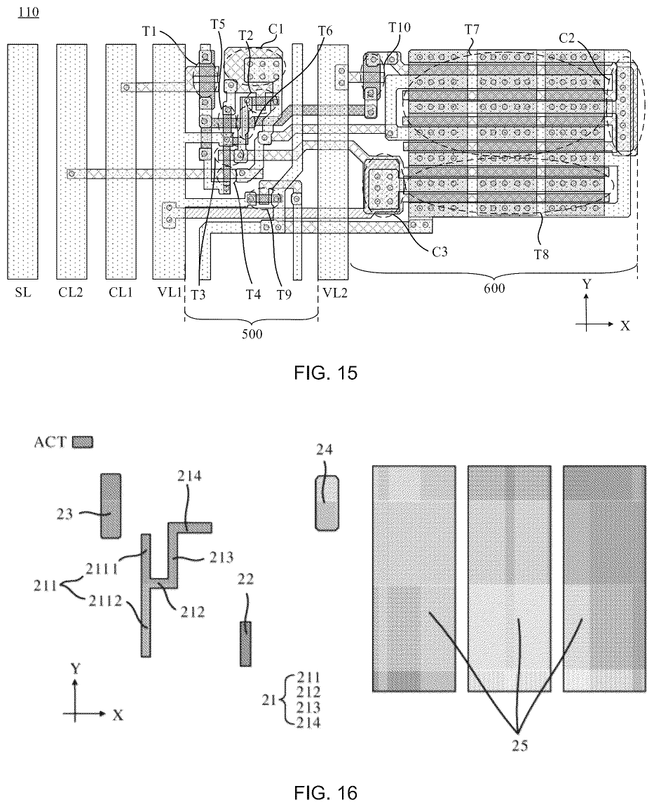

Referring to FIGS. 14 and 15, the array substrate 110 provided in some embodiments of the present disclosure further includes a first voltage signal line VL1 and a second voltage signal line VL2, both of the first voltage signal line VL1 and the second voltage signal line VL2 extending substantially along the second direction Y.

It will be noted that the first voltage signal line VL1 is configured to provide a constant high voltage, and the second voltage signal line VL2 is configured to provide a constant low voltage.

As shown in FIGS. 4, 14 and 15, the first voltage signal line VL1 is disposed on a side of the gate driving circuit 10 away from the display area A; and the second voltage signal line VL2 overlaps with the gate driving circuit 10 and divides the first shift register RS1 of the gate driving circuit 10 into a first circuit 500 and a second circuit 600, in which the first circuit 500 is farther away from the display area A than the second circuit 600.

In this case, as shown in FIGS. 6, 14 and 15, the first voltage signal terminal VGH is connected to the first voltage signal line VL1, the second voltage signal terminal VS is connected to the first voltage signal line VL1 or the second voltage signal line VL2, and the third voltage signal terminal VGL is connected to the second voltage signal line VL2.

In some embodiments, referring to FIGS. 14 and 15, the array substrate 110 further includes a first clock signal line CL1, a second clock signal line CL2 and an initialization signal line SL. The first clock signal line CL1, the second clock signal line CL2 and the initialization signal line SL all extend substantially along the second direction Y, i.e., substantially parallel to the first voltage signal line VL1.

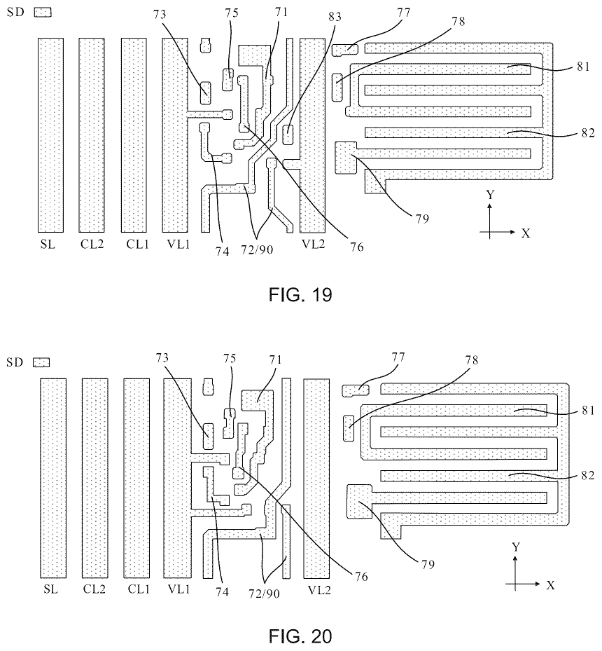

It will be noted that there may be multiple first clock signal lines CL1 and multiple second clock signal lines CL2, FIGS. 14, 15, 19 and 20 are only exemplified taking an example where there are a single first clock signal line CL1 and single second clock signal line CL2, and the embodiments of the present disclosure are not limited thereto.

Referring to FIGS. 4, 14 and 15, the first clock signal line CL1, the second clock signal line CL2 and the initialization signal line SL are disposed on a side of the gate driving circuit 10 away from the display area A.

For example, as shown in FIGS. 4, 14 and 15, the first clock signal line CL1, the second clock signal line CL2 and the initialization signal line SL may be arranged away from the first voltage signal line VL1 in sequence.

In this case, as shown in FIGS. 6, 14 and 15, the first clock signal terminal CK is connected to the first clock signal line CL1, the second clock signal terminal CB is connected to the second clock signal line CL2, and a signal input terminal IN of a first shift register RS1 at the first stage is connected to the initialization signal line SL.

In some embodiments, referring to FIG. 16, the array substrate 110 further includes a first active pattern 21, a second active pattern 22, a third active pattern 23, a fourth active pattern 24, and a fifth active pattern 25.

In some examples, as shown in FIG. 16, the first active pattern 21 includes a first straight line segment 211, a second straight line segment 212, a third straight line segment 213, and a fourth straight line segment 214.

Here, as shown in FIGS. 14, 15 and 16, the first straight line segment 211 and the third straight line segment 213 both are substantially parallel to the first voltage signal line VL1, and the first straight line segment 211 is closer to the first voltage signal line VL1 than the third straight line segment 213; and the second straight line segment 212 and the fourth straight line segment 214 both are substantially perpendicular to the first voltage signal line VL1.

In addition, as shown in FIG. 16, the first straight line segment 211 includes a first portion 2111 and a second portion 2112, where the first portion 2111 and the second portion 2112 are located on two opposite sides of the second straight line segment 212; and the second straight line segment 212, the third straight line segment 213 and the fourth straight line segment 214 are connected in sequence at end portions thereof, and the third straight line segment 213 and the first portion 2111 are located on a same side of the second straight line segment 212.

Referring to FIGS. 9, 14 and 16, active layers of transistors included in the first control sub-circuit 51 described above are located in the second portion 2112 of the first straight line segment 211 in the first active pattern 21. For example, active layers of the third transistor T3 and the fourth transistor T4 are located in the second portion 2112 of the first straight line segment 211 in the first active pattern 21.

Referring to FIGS. 9, 14 and 16, in transistors included in the second control sub-circuit 52 described above, an active layer of a part of the transistors is located in the first portion 2111 of the first straight line segment 211 in the first active pattern 21, and an active layer of the other part of the transistors is located in the third straight line segment 213. For example, an active layer of the fifth transistor T5 is located in the first portion 1211, and an active layer of the sixth transistor T6 is located in the third straight line segment 213.

Referring to FIGS. 9, 14 and 16, an active layer of a transistor included in the second input circuit 40 described above is located in the fourth straight line segment 214. For example, an active layer of the second transistor T2 is located in the fourth straight line segment 214.

In some examples, as shown in FIGS. 14 and 16, the second active pattern 22 may be located at a side of the first active pattern 21 away from the first voltage signal line VL1.

In this case, referring to FIGS. 9, 14 and FIG. 16, an active layer of a transistor included in the output control circuit 70 described above is located in the second active pattern 22. For example, an active layer of the ninth transistor T9 is located in the second active pattern 22.

In some examples, as shown in FIGS. 9, 14 and 16, the third active pattern 23 is located on a side of the first active pattern 21 proximate the first voltage signal line VL1. Here, the third active pattern 23 may be substantially parallel to the first voltage signal line VL1.

In this case, an active layer of a transistor included in the first input circuit 30 described above is located in the third active pattern 23. For example, an active layer of the first transistor T1 is located in the third active pattern 23.

In some examples, as shown in FIGS. 9, 14 and 16, the fourth active pattern 24 is located on a side of the second voltage signal line VL2 away from the first voltage signal line VL1. Here, the fourth active pattern 24 may be substantially parallel to the first voltage signal line VL1.

In this case, an active layer of a transistor included in the isolation sub-circuit 80 described above is located in the fourth active pattern 24. For example, an active layer of the tenth transistor T10 is located in the fourth active pattern 24.

In some examples, as shown in FIGS. 9, 14 and 16, the fifth active pattern 25 is located on a side of the fourth active pattern 24 away from the first voltage signal line VL1. Here, the fifth active pattern 25 may include multiple active sub-patterns arranged at intervals along the first direction X.

In this case, active layers of transistors included in the first output circuit 60 described above are located in the fifth active pattern 25. For example, active layers of the seventh transistor T7 and the eighth transistor T8 are located in the fifth active pattern 25.

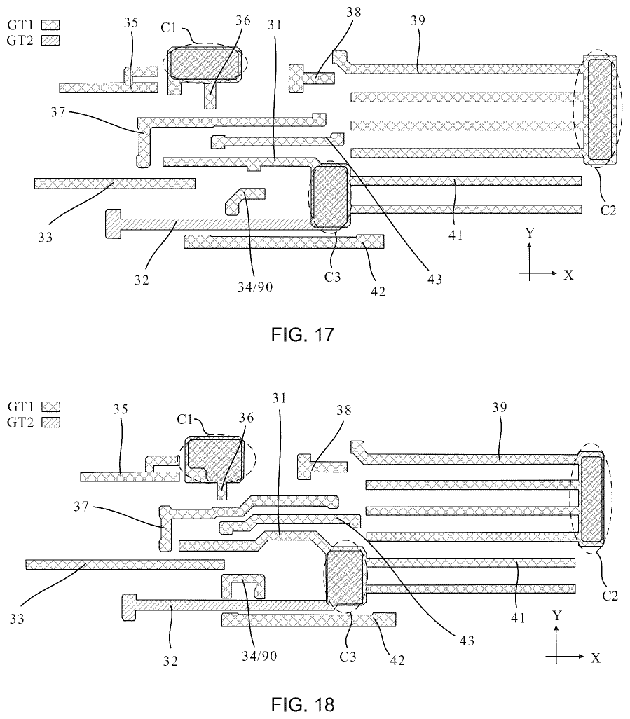

In some embodiments, referring to FIGS. 14, 15, 17 and 18, the array substrate 110 further includes a first gate line 31, a second gate line 32, a third gate line 33, a fourth gate line 34, a fifth gate line 35, a sixth gate line 36, a seventh gate line 37, an eighth gate line 38, a ninth gate line 39, a tenth gate line 41, and an eleventh gate line 42.

In some examples, as shown in FIGS. 9, 14 and 17, the first gate line 31 is substantially perpendicular to the first voltage signal line VL1. The first gate line 31 overlaps with the second portion 2112 of the first straight line segment 211 in the first active pattern 21, and is connected to the second control subcircuit 52 and the first output circuit 60.

For example, as shown in FIGS. 9, 14 and 17, the first gate line 31 overlaps with the second portion 2112 of the first straight line segment 211 in the first active pattern 21 to form the third transistor T3, and is connected to a connection node (the second node N2) of the second transistor T2 and the sixth transistor T6, as well as, connected to the third electrode of the eighth transistor T8.

Here, as shown in FIGS. 9, 14 and 17, the array substrate 110 described above may further include a first electrode plate and a second electrode plate of the third capacitor C3, where at least a portion of the first electrode plate and at least a portion of the second electrode plate overlap with each other. The first gate line 31 is further connected to the first electrode plate of the third capacitor C3.

In some examples, as shown in FIGS. 9, 14 and 17, the second gate line 32 is substantially perpendicular to the first voltage signal line VL1, and the second gate line 32 is connected to the first voltage signal line VL1 and the first output circuit 60.

For example, as shown in FIGS. 9, 14 and 17, the second gate line 32 is connected to the first voltage signal line VL1, as well as, to the first electrode of the eighth transistor T8.

Here, as shown in FIGS. 9, 14 and 17, the array substrate 110 described above may further include a first electrode plate and a second electrode plate of the third capacitor C3, where at least a portion of the first electrode plate and at least a portion of the second electrode plate overlap with each other. The second gate line 32 is further connected to the second electrode plate of the third capacitor C3.

In some examples, as shown in FIGS. 9, 14 and 17, the third gate line 33 is substantially perpendicular to the first voltage signal line VL1. The third gate line 33 is located between the first gate line 31 and the second gate line 32. One end of the third gate line 33 is connected to the second clock signal line CL2, and the other end overlaps with the second portion 2112 of the first straight line segment 211 in the first active pattern 21 to form the fourth transistor T4.

In some examples, as shown in FIGS. 9, 14 and 17, the fourth gate line 34 is located between the first gate line 31 and the second gate line 32. The fourth gate line 34 overlaps with the second active pattern 22 to form the ninth transistor T9.

In some examples, as shown in FIGS. 9, 14 and 17, the fifth gate line 35 is substantially perpendicular to the first voltage signal line VL1. The fifth gate line 35 is located on a side of the first gate line 31 away from the second gate line 32, and one end of the fifth gate line 35 is connected to the first clock signal line CL1, and the other end overlaps with the third active pattern 23 to form the first transistor T1.

In some examples, as shown in FIGS. 9, 14 and 17, the sixth gate line 36 is substantially parallel to the first voltage signal line VL1. The sixth gate line 36 is located on a side of the fifth gate line 35 away from the first voltage signal line VL1, and overlaps with the fourth straight line segment 214 to form the second transistor T2.

Here, as shown in FIGS. 9, 14 and 17, the array substrate 110 described above may further include a first electrode plate and a second electrode plate of the first capacitor C1, where at least a portion of the first electrode plate and at least a portion of the second electrode plate overlap with each other. The sixth gate line 36 is further connected to the second electrode plate of the first capacitor C1.

In some examples, as shown in FIGS. 9, 14 and 17, the seventh gate line 37 overlaps with the first portion 2111 of the first straight line segment 211 in the first active pattern 21 and the third straight line segment 213, so as to form the fifth transistor T5 and the sixth transistor T6, respectively.

In some examples, as shown in FIGS. 9, 14 and 17, one end of the eighth gate line 38 is connected to the second voltage signal line VL2, and the other end overlaps with the fourth active pattern to form the tenth transistor T10.

In some examples, as shown in FIGS. 9, 14 and 17, the ninth gate line 39 overlaps with the fifth active pattern 25 to form the seventh transistor T7.

Here, as shown in FIGS. 9, 14 and 17, the array substrate 110 described above may further include a first electrode plate and a second electrode plate of the second capacitor C2, where at least a portion of the first electrode plate and at least a portion of the second electrode plate overlap with each other. The ninth gate line 39 is further connected to the first electrode plate of the first capacitor C2.

In some examples, as shown in FIGS. 9, 14 and 17, the tenth gate line 41 is connected to the first gate line 31, and overlaps with the fifth active pattern 25 to form the eighth transistor T8.

Here, as shown in FIGS. 9, 14 and 17, the array substrate 110 described above may further include a first electrode plate and a second electrode plate of the third capacitor C3, where at least a portion of the first electrode plate and at least a portion of the second electrode plate overlap with each other. The tenth gate line 41 is further connected to the first electrode plate of the third capacitor C3.

In some examples, as shown in FIGS. 9, 14 and 17, the eleventh gate line 42 is connected to the second electrodes of the seventh transistor T7 and the eighth transistor T8, and extends to a region between the first voltage signal line VL1 and the second voltage signal line VL2.

In some embodiments, referring to FIGS. 14, 15, 19 and 20, the array substrate 110 further includes a first connection line 71, a second connection line 72, a third connection line 73, a fourth connection line 74, a fifth connection line 75, a sixth connection line 76, a seventh connection line 77, an eighth connection line 78, a ninth connection line 79, a tenth connection line 81, and an eleventh connection line 82.

In some examples, as shown in FIGS. 14, 16, 17 and 19, the first connection line 71 is connected to the first electrode of the second transistor T2 and the third electrode of the fourth transistor T4. That is, the first connection line 71 is connected to an end portion of the fourth straight line segment 214 away from the third straight line segment 213, and connected to an end portion of the third gate line 33 away from the first voltage signal line VL1.

It will be noted that the first connection line 71 is connected to a first electrode plate of a first capacitor C1.

In this case, as shown in FIGS. 14, 17 and 19, the array substrate 110 described above may further include the first capacitor C1 and a twelfth gate line 43. The twelfth gate line 43 is connected to the first connection line 71 and the first electrode of the seventh transistor T7, and the first connection line 71 may be further connected to a first electrode plate of the first capacitor C1.

Here, an end portion of the first connection line 71 connected to the fourth straight line segment 214 is farther away from the first voltage signal line VL1 than an end portion thereof connected to the third gate line 33. With such a configuration, a distance between the first connection line 71 and the second voltage signal line VL2 is made large, which facilitates the provision of the output control circuit 70.

In some examples, as shown in FIGS. 14, 17 and 19, the second connection line 72 is connected to the fourth gate line 34 and a signal output terminal OT (refer to FIG. 6) of a shift register RS (refer to FIG. 6) at a next stage. That is, one end of the second connection line 72 may be connected to the fourth gate line 34, and the other end may be connected to a portion of an eleventh gate line 42 of the shift register RS (refer to FIG. 6) at the next stage extending to a region between the first voltage signal line VL1 and the second voltage signal line VL2.

In some examples, as shown in FIGS. 14, 16, 17 and 19, the third connection line 73 is connected to the second electrode of the first transistor T1 and the third electrodes of the fifth transistor T5 and the sixth transistor T6. That is, one end of the third connection line 73 may be connected to the third active pattern 23, and the other end may be connected to the seventh gate line 37.

In some examples, as shown in FIGS. 14, 17 and 19, the fourth connection line 74 is connected to the third electrodes of the fifth transistor T5 and the sixth transistor T6, and the second electrode of the fourth transistor T4. That is, one end of the fourth connection line 74 may be connected to the seventh gate line 37, and the other end may be connected to an end of the second portion 2112 of the first straight line segment 211 in the first active pattern 21 away from the first portion 2111 of the first straight line segment 211 in the first active pattern 21.

In some examples, as shown in FIGS. 14, 16, 17 and 19, the fifth connection line 75 is connected to the second electrode of the fifth transistor T5 and the second electrode plate of the first capacitor C1. That is, one end of the fifth connection line 75 may be connected to an end of the first portion 2111 of the first straight line segment 211 in the first active pattern 21 away from the second portion 2112 of the first straight line segment 211 in the first active pattern 21, and the other end may be connected to the second electrode plate of the first capacitor C1.

In some examples, as shown in FIGS. 14, 16, 17 and 19, the sixth connection line 76 is connected to the second electrodes of the second transistor T2 and the sixth transistor T6, and the third electrodes of the third transistor T3 and the eighth transistor T8. That is, one end of the sixth connection line 76 may be connected to an inflection point of the third straight line segment 213 and the fourth straight line segment 214, and the other end may be connected to the first gate line 31.

In some examples, as shown in FIGS. 14, 16, 17 and 19, the seventh connection line 77 is connected to the second electrode of the tenth transistor T10 and the third electrode of the seventh transistor T7. That is, one end of the seventh connection line 77 may be connected to the fourth active pattern 24, and the other end may be connected to the ninth gate line 39.

In some examples, as shown in FIGS. 14, 16, 17 and 19, the eighth connection line 78 is connected to the first electrode of the tenth transistor T10, and the third electrodes of the fifth transistor T5 and the sixth transistor T6. That is, one end of the eighth connection line 78 may be connected to the fourth active pattern 24, and the other end may be connected to the seventh gate line 37.

In some examples, as shown in FIGS. 14, 16, 17 and 19, the ninth connection line 79 is connected to the second electrode plate of the third capacitor C3 and the first electrode of the eighth transistor T8. That is, one end of the ninth connection line 79 is connected to the second electrode plate of the third capacitor C3, and the other end of the fifth active pattern 25.

In some examples, as shown in FIGS. 14, 16, 17 and 19, the tenth connection line 81 is connected to the first electrode of the seventh transistor T7 and the second clock signal line CL2. In this case, the array substrate 110 described above may further include a twelfth gate line 43, and the twelfth gate line 43 is connected to the first connection line 71 and the tenth connection line 81.

In some examples, as shown in FIGS. 14, 16, 17 and 19, the eleventh connection line 82 is connected to the second electrode plate of the second capacitor C2, the second electrodes of the seventh transistor T7 and the eighth transistor T8, and forms the signal output terminal OT. In this case, the eleventh gate line 42 described above is connected to the eleventh connection line 82.

In some embodiments, as shown in FIGS. 9 and 14, the output control circuit 70 described above is coupled to the second voltage signal terminal VS, the control signal terminal K and the second node N2.

On this basis, referring to FIGS. 14, 16 and 17, the second active pattern 22 described above is substantially parallel to the first voltage signal line VL1. One end of the second active pattern 22 is connected to the first gate line 31, and the other end is connected to the second voltage signal line VL2.

Here, as shown in FIGS. 14, 16, 17 and 19, the array substrate 110 described above may further include a twelfth connection line 83. The second active pattern 22 is connected to the twelfth connection line 83, and the twelfth connection line 83 is electrically connected to the first gate line 31, thereby enabling the second active pattern 22 to be electrically connected to the first gate line 31.

Here, the array substrate 110 described above may further include a first cascade line 90. For shift registers RS at two adjacent stages, one end of the first cascade line 90 overlaps with a second active pattern 22 of the shift register RS at a former stage, and the other end passes through the first connection line 71 and the second voltage signal line VL2 and is connected to a signal output terminal OT of the shift register RS at a latter stage.

In this case, the first cascade line 90 includes the second connection line 72 and the fourth gate line 34, and the second connection line 72 is connected to the fourth gate line 34 and the signal output terminal OT of the shift register RS at the latter stage.

In some other embodiments, referring to FIGS. 10 and 15, the output control circuit 70 is coupled to the second voltage signal terminal VS, the control signal terminal K and the signal output terminal OT.

On this basis, referring to FIGS. 15 and 16, the second active pattern 22 is substantially perpendicular to the first voltage signal line VL1. One end of the second active pattern 22 is connected to the signal output terminal OT (refer to FIG. 10), and the other end is connected to the first voltage signal line VL1.

Here, the array substrate 110 described above may further include a first cascade line 90. For shift registers RS at two adjacent stages, one end of the first cascade line 90 overlaps with a second active pattern 22 of the shift register RS at a former stage, and the other end passes through the first connection line 71 and the second voltage signal line VL2 and is connected to a signal output terminal OT of the shift register RS at a latter stage.

In this case, as shown in FIGS. 15, 16, 18 and 20, the first cascade line 90 includes the second connection line 72 and the fourth gate line 34, one end of the fourth gate line 34 overlaps with the second active pattern 22, and the other end is connected to the second connection line 72 across another first cascade line 90. The second connection line 72 is connected to the fourth gate line 34 and the signal output terminal OT of the shift register RS at the latter stage.

Based on the above wiring design, along the first direction X, the width of the first shift register RS1 is approximately equal to the width of the second shift register RS2. That is, this gate driving circuit 10 may be equipped with an output control circuit 70 while the width thereof along the first direction X remains unchanged, so as to enhance the stability of the gate driving circuit 10 against interference, to reduce the risk of erroneous writing or writing failure of the data of the sub-pixels P, thereby improving the display quality.

For example, in a case where a longitudinal maximum dimension of the sub-pixel P ranges from 110 μm to 120 μm, the width of the gate driving circuit 10 ranged from 380 μm to 390 μm along the first direction X.

FIG. 5 is a sectional view taken along the section line B-B′ in FIG. 4. Film layers where the wirings in the array substrate 110 are located provided by some embodiments of the present disclosure are schematically illustrated below in conjunction with FIG. 5, and the embodiments of the present disclosure are not limited thereto.

As shown in FIG. 5, along a direction perpendicular to the base 11 and away from the base 11, the array substrate 110 includes a semiconductor layer ACT, a gate insulating layer GI, a first gate conductive layer GT1, a first interlayer insulating layer ILD1, a second gate conductive layer GT2, a second interlayer insulating layer ILD2, a source-drain conductive layer SD and a planarization layer PLN, which are disposed in sequence on the base 11.

Referring to FIGS. 5 and 16, the first active pattern 21, the second active pattern 22, the third active pattern 23, the fourth active pattern 24, and the fifth active pattern 25 described above are located in the semiconductor layer ACT.

Referring to FIGS. 5, 17 and 18, the first gate line 31, the third gate line 33, the fourth gate line 34, the fifth gate line 35, the sixth gate line 36, the seventh gate line 37, the eighth gate line 38, the ninth gate line 39, the tenth gate line 41, the eleventh gate line 42, and the twelfth gate line 43 described above are located in the first gate conductive layer GT1; and the second gate line 32 described above is located in the second gate conductive layer GT2.

Referring to FIGS. 5, 19 and 20, the first connection line 71, the second connection line 72, the third connection line 73, the fourth connection line 74, the fifth connection line 75, the sixth connection line 76, the seventh connection line 77, the eighth connection line 78, the ninth connection line 79, the tenth connection line 81, the eleventh connection line 82, and the twelfth connection line 83 described above are located in the source-drain conductive layer SD.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A shift register, comprising:
a first input circuit, coupled to a signal input terminal, a first clock signal terminal and a first node, the first input circuit being configured to, under control of a first clock signal from the first clock signal terminal, transmit an input signal from the signal input terminal to the first node;
a second input circuit, coupled to a second clock signal terminal, a second node and a third node, the second input circuit being configured to, under control of a voltage of the third node, transmit a second clock signal from the second clock signal terminal to the second node;
a first output circuit, coupled to the first node, the second node, a first voltage signal terminal, the second clock signal terminal and a signal output terminal, the first output circuit being configured to, under control of a voltage of the first node, transmit the second clock signal from the second clock signal terminal to the signal output terminal, and under control of a voltage of the second node, transmit a first voltage signal from the first voltage signal terminal to the signal output terminal; and
an output control circuit, coupled to a second voltage signal terminal and a control signal terminal, and further coupled to the second node or the signal output terminal, the output control circuit being configured to, under control of a control signal from the control signal terminal, transmit a second voltage signal from the second voltage signal terminal to the second node or the signal output terminal.

2. The shift register according to claim 1, wherein the output control circuit is coupled to the second voltage signal terminal, the control signal terminal and the second node; and
of the voltage signals received by the first voltage signal terminal and the second voltage signal terminal, one is an operating voltage enabling a transistor to which the operating voltage is applied to be turned on, and the other is a non-operating voltage enabling a transistor to which the operating voltage is applied to be turned off.

3. The shift register according to claim 2, wherein the output control circuit comprises:
a ninth transistor, a first electrode of the ninth transistor being electrically connected to the second voltage signal terminal, a second electrode of the ninth transistor being electrically connected to the second node, and a third electrode of the ninth transistor being electrically connected to the control signal terminal.

4. The shift register according to claim 1, wherein the output control circuit is coupled to the second voltage signal terminal, the control signal terminal and the signal output terminal; and the voltage signals received by the first voltage signal terminal and the second voltage signal terminal are the same.

5. The shift register according to claim 4, wherein the output control circuit comprises:
a ninth transistor, a first electrode of the ninth transistor being electrically connected to the second voltage signal terminal, a second electrode of the ninth transistor being electrically connected to the signal output terminal, and a third electrode of the ninth transistor being electrically connected to the control signal terminal.

6. The shift register according to claim 1, wherein the first input circuit comprises:
a first transistor, a first electrode of the first transistor being electrically connected to the signal input terminal, a second electrode of the first transistor being electrically connected to the first node, and a third electrode of the first transistor being electrically connected to the first clock signal terminal;
and/or the second input circuit comprises:
a second transistor, a first electrode of the second transistor being electrically connected to the second clock signal terminal, a second electrode of the second transistor being electrically connected to the second node, and a third electrode of the second transistor being electrically connected to the third node; and
a first capacitor, a first electrode plate of the first capacitor being electrically connected to the second clock signal terminal, and a second electrode plate of the first capacitor being electrically connected to the third node.

7. The shift register according to claim 1, wherein the first output circuit comprises:
a seventh transistor, a first electrode of the seventh transistor being electrically connected to the second clock signal terminal, a second electrode of the seventh transistor being electrically connected to the signal output terminal, and a third electrode of the seventh transistor being electrically connected to the first node;
an eighth transistor, a first electrode of the eighth transistor being electrically connected to the first voltage signal terminal, a second electrode of the eighth transistor being electrically connected to the signal output terminal, and a third electrode of the eighth transistor being electrically connected to the second node;
a second capacitor, a first electrode plate of the second capacitor being electrically connected to the first node, and a second electrode plate of the second capacitor being electrically connected to the signal output terminal; and
a third capacitor, a first electrode plate of the third capacitor being electrically connected to the second node, and a second electrode plate of the third capacitor being electrically connected to the first voltage signal terminal.

8. The shift register according to claim 1, further comprising:
a control circuit, coupled to the first node, the second node, the third node and the first voltage signal terminal, the control circuit being configured to, under the control of the voltage from the first node, transmit the first voltage signal from the first voltage signal terminal to the second node and the third node, and under the control of the voltage from the second node, transmit the first voltage signal from the first voltage signal terminal to the first node.

9. The shift register according to claim 8, wherein the control circuit comprises:
a first control sub-circuit, coupled to the first node, the second node and the first voltage signal terminal, the first control sub-circuit being configured to, under the control of the voltage of the second node, transmit the first voltage signal from the first voltage signal terminal to the first node; and
a second control sub-circuit, coupled to the first node, the second node, the third node and the first voltage signal terminal, the second control sub-circuit being configured to, under the control of the voltage of the first node, transmit the first voltage signal from the first voltage signal terminal to the second node and the third node.

10. The shift register according to claim 9, wherein the first control sub-circuit is further coupled to the second clock signal terminal, and the first control sub-circuit comprises:
a third transistor, a first electrode of the third transistor being electrically connected to the first voltage signal terminal, a second electrode of the third transistor being electrically connected to the first node, and a third electrode of the third transistor being electrically connected to the second node; and
a fourth transistor, a first electrode of the fourth transistor being electrically connected to the second electrode of the third transistor, a second electrode of the fourth transistor being electrically connected to the first node, and a third electrode of the fourth transistor being electrically connected to the second clock signal terminal;
and/or the second control sub-circuit comprises:
a fifth transistor, a first electrode of the fifth transistor being electrically connected to the first voltage signal terminal, a second electrode of the fifth transistor being electrically connected to the third node, and a third electrode of the fifth transistor being electrically connected to the first node; and
a sixth transistor, a first electrode of the sixth transistor being electrically connected to the first voltage signal terminal, a second electrode of the sixth transistor being electrically connected to the second node, and a third electrode of the sixth transistor being electrically connected to the first node.

11. A gate driving circuit, comprising a plurality of first shift registers connected in cascade, the first shift registers being shift registers each as claimed in claim 1.

12. The gate driving circuit according to claim 11, wherein except for a first shift register at a last stage, for first shift registers at every two adjacent stages, a control signal terminal of a first shift register at a former stage is coupled to a signal output terminal of a first shift register at a later stage; or
except for a first shift at a last stage, for first shift registers at every two adjacent stages, a control signal terminal of a first shift register at a former stage is coupled to a signal output terminal of a first shift register at a latter stage, and the gate driving circuit further comprises a second shift register, the second shift register comprising:
a first input circuit, a second input circuit, a control circuit and a first output circuit, wherein a signal input terminal of the second shift register is connected to a signal output terminal of the first shift register at the last stage, and a control signal terminal of the first shift register at the last stage is connected to signal output terminal of the second shift register.

13. (canceled)

14. An array substrate, having a display area and a peripheral area located on at least one side of the display area, the array substrate comprising:
a base; and
the gate driving circuit as claimed in claim 11, the gate driving circuit being disposed on the base and located in the peripheral area.

15. The array substrate according to claim 14, further comprising:
a first voltage signal line, disposed on a side of the gate driving circuit away from the display area; and
a second voltage signal line, overlapping with the gate driving circuit and dividing a first shift register of the gate driving circuit into a first circuit and a second circuit, wherein the first circuit is farther away from the display area than the second circuit;
wherein the first circuit comprises a first input circuit, a second input circuit, a control circuit and an output control circuit; and the second circuit comprises a first output circuit.

16. The array substrate according to claim 15, wherein the control circuit comprises a first control sub-circuit and a second control sub-circuit; and the array substrate further comprises:
a first active pattern, comprising a first straight line segment, a second straight line segment, a third straight line segment and a fourth straight line segment, wherein the first straight line segment and the third straight line segment both are substantially parallel to the first voltage signal line, and the first straight line segment is closer to the first voltage signal line than the third straight line segment; and the second straight line segment and the fourth straight line segment both are substantially perpendicular to the first voltage signal line;
wherein the first straight line segment comprises a first portion and a second portion, the first portion and the second portion being located on two opposite sides of the second straight line segment; and the second straight line segment, the third straight line segment, and the fourth straight line segment are connected in sequence at end portions thereof, and the third straight line segment and the first portion are located on a same side of the second straight line segment; and
active layers of transistors comprised in the first control sub-circuit are located in the second portion; and in transistors comprised in the second control sub-circuit, an active layer of a part of the transistors is located in the first portion, and an active layer of the other part of the transistors is located in the third straight line segment.

17. The array substrate according to claim 16, wherein the output control circuit is coupled to a second voltage signal terminal, a control signal terminal and a second node; and
the array substrate further comprises:
a first gate line, substantially perpendicular to the first voltage signal line, the first gate line overlapping with the second portion and being connected to the second control sub-circuit and the first output circuit;
a second gate line, substantially perpendicular to the first voltage signal line, the second gate line being connected to the first voltage signal line and the first output circuit; and
a second active pattern, substantially parallel to the first voltage signal line and located between the first gate line and the second gate line, wherein one end of the second active pattern is connected to the first gate line, and the other end of the second active pattern is connected to the second voltage signal line; and an active layer of a transistor comprised in the output control circuit is located in the second active pattern.

18. The array substrate according to claim 17, further comprising:
a second clock signal line, disposed on the side of the gate driving circuit away from the display area and substantially parallel to the first voltage signal line;
a third gate line, substantially perpendicular to the first voltage signal line, wherein one end of the third gate line is connected to the second clock signal line, and the other end of the third gate line overlaps with the second portion;
a first connection line, connected to an end portion of the fourth straight line segment away from the third straight line segment, and connected to an end portion of the third gate line away from the first voltage signal line; and
a first cascade line, wherein for shift registers at two adjacent stages, one end of the first cascade line overlaps with a second active pattern of a shift register at a former stage, and the other end of the first cascade line passes through the first connection line and the second voltage signal line and is connected to a signal output terminal of a shift register at a latter stage.

19. (canceled)

20. The array substrate according to claim 16, wherein the output control circuit is coupled to a second voltage signal terminal, a control signal terminal and a signal output terminal; and
the array substrate further comprises:
a first gate line, substantially perpendicular to the first voltage signal line, the first gate line overlapping with the second portion and being connected to the second control sub-circuit and the first output circuit;
a second gate line, substantially perpendicular to the first voltage signal line, the second gate line being connected to the first voltage signal line and the first output circuit; and
a second active pattern, substantially perpendicular to the first voltage signal line and located between the first gate line and the second gate line, wherein one end of the second active pattern is connected to the signal output terminal, and the other end of the second active pattern is connected to the first voltage signal line; and an active layer of a transistor comprised in the output control circuit is located in the second active pattern.

21. The array substrate according to claim 20, further comprising:
a second clock signal line, disposed on the side of the gate driving circuit away from the display area and substantially parallel to the first voltage signal line;
a third gate line, substantially perpendicular to the first voltage signal line, wherein one end of the third gate line is connected to the second clock signal line, and the other end of the third gate line overlaps with the second portion;
a first connection line, connected to an end portion of the fourth straight line segment away from the third straight line segment, and connected to an end portion of the third gate line away from the first voltage signal line; and
a first cascade line, wherein for shift registers at two adjacent stages, one end of the first cascade line overlaps with a second active pattern of a shift register at a former stage, and the other end of the first cascade line passes through the first connection line and the second voltage signal line and is connected to a signal output terminal of a shift register at a latter stage.

22. (canceled)

23. (canceled)

24. A display device, comprising the array substrate as claimed in claim 14.
